(19) United States
(12) Patent Application Publication
(10) Pub. No.: US 2025/0372369 A1
(43) Pub. Date: Dec. 4, 2025

(54) METHODS OF FABRICATING HIGH-K GATE STRUCTURES

(71) Applicant: Applied Materials, Inc., Santa Clara, CA (US)

(72) Inventors: Prasad Bhosale, San Jose, CA (US); Steven C.H. Hung, Sunnyvale, CA (US); Theresa K. Guarini, San Jose, CA (US); Yan Yan, Rexford, NY (US); Johanes F. Swenberg, Los Gatos, CA (US); Paola de Cecco, Salinas, CA (US); Joseph Shepard, Saratoga Springs, NY (US); Mark Conrad, Cohoes, NY (US); Brian K. Kirkpatrick, Allen, TX (US)

(73) Assignee: Applied Materials, Inc., Santa Clara, CA (US)

(21) Appl. No.: 19/215,764

(22) Filed: May 22, 2025

Related U.S. Application Data
(60) Provisional application No. 63/655,308, filed on Jun. 3, 2024.
(60) Provisional application No. 63/725,650, filed on Nov. 27, 2024.

(51) Int. Cl. H01L 21/02

(52) U.S. Cl. CPC H01L 21/02343; H01L 21/0206; H01L 21/02236

(57) ABSTRACT

Processing methods may be performed to produce semiconductor structures that include a high-k dielectric material. The methods include pre-cleaning a semiconductor substrate surface. An interfacial layer is formed on the substrate surface by exposing the substrate to an oxidizing atmosphere and thermally annealing the surface. The interfacial layer is treated with hydration chemistry to form a treated interfacial layer, followed by deposition of a high-k dielectric layer on the treated interfacial layer.

### CROSS-REFERENCE TO RELATED APPLICATIONS

This application claims priority to U.S. Provisional Application No. 63/725,650, filed Nov. 27, 2024, and to U.S. Provisional Application No. 63/655,308, filed Jun. 3, 2024, the entire disclosures of which are hereby incorporated by reference herein.

### TECHNICAL FIELD

Embodiments of the present disclosure generally relate to semiconductor devices, systems, processes, equipment, and fabrication. More particularly, embodiments relate to treatments to enhance device performance in gate structures.

### BACKGROUND

As metal-oxide-semiconductor field-effect transistors (MOSFETs) have decreased in size to achieve high device performance and low power consumption, the thickness of a traditional silicon dioxide (SiO₂) gate dielectric has decreased to its physical limit. As a result, replacing the silicon dioxide gate dielectric with a high-K dielectric material has been inevitable to achieve further scaling. Among various high-K dielectric materials, hafnium oxide (HfO₂) has been applied since the 45 nm MOSFET technology node due to its high dielectric constant and superior thermal stability on a silicon substrate. Poor nucleation of high-K dielectric material on thermally grown silicon oxide is problematic due to an increase of leakage in the gate dielectric stack.

Thus, there is a need for systems and methods that can be used to improve high-K dielectric material nucleation on thermal oxide with less defective interface and bulk film. Reduction in defects may provide reduced leakage in the gate dielectric stack.

### SUMMARY

One or more embodiments of the disclosure are directed to methods of forming a semiconductor device. In one or more embodiments, the method comprises: pre-cleaning a substrate surface to remove native oxide and form a pre-cleaned substrate surface; exposing the pre-cleaned substrate surface to an oxidizing atmosphere and thermally annealing to form an interfacial layer on the pre-cleaned substrate surface; exposing the interfacial layer to an ambient atmosphere, the interfacial layer exposed to the ambient atmosphere for a first time period; treating the interfacial layer with hydration chemistry to form a treated interfacial layer, the interfacial layer treated with hydration chemistry for a second time period; and depositing a high-K dielectric layer on the treated interfacial layer.

One or more embodiments of the disclosure are directed to methods of forming a semiconductor device. In one or more embodiments, the method comprises: pre-cleaning a substrate in a first semiconductor processing chamber to remove native oxide and form a pre-cleaned substrate surface; transferring the substrate to a second semiconductor processing chamber without breaking vacuum conditions; exposing the pre-cleaned substrate surface to an oxidizing atmosphere and thermally annealing to form an interfacial layer on the pre-cleaned substrate surface; transferring the substrate to a third semiconductor processing chamber while exposing the interfacial layer to an ambient atmosphere, the interfacial layer exposed to the ambient atmosphere for a first time period; treating the interfacial layer with hydration chemistry to form a treated interfacial layer, the treating of the interfacial layer occurring for a second time period; transferring the substrate to a fourth semiconductor processing chamber without breaking vacuum conditions; and depositing a high-K dielectric layer on the treated interfacial layer.

### BRIEF DESCRIPTION OF THE DRAWINGS

So that the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope.

FIG. 1 illustrates a schematic top-view diagram of an example multi-chamber processing system according to one or more embodiments;

FIG. 2A illustrates a process flow diagram of a method of forming a semiconductor structure according to one or more embodiments;

FIG. 2B illustrates a process flow diagram of a method of forming a semiconductor structure according to one or more embodiments;

FIG. 3A illustrates schematic views of a semiconductor structure according to one or more embodiments;

FIG. 3B illustrates schematic views of a semiconductor structure according to one or more embodiments;

FIG. 3C illustrates schematic views of a semiconductor structure according to one or more embodiments;

FIG. 3D illustrates schematic views of a semiconductor structure according to one or more embodiments;

FIG. 3E illustrates schematic views of a semiconductor structure according to one or more embodiments;

FIG. 3F illustrates schematic views of a semiconductor structure according to one or more embodiments;

FIG. 4A illustrates schematic views of a semiconductor structure according to one or more embodiments;

FIG. 4B illustrates schematic views of a semiconductor structure according to one or more embodiments;

FIG. 4C illustrates schematic views of a semiconductor structure according to one or more embodiments;

FIG. 4D illustrates schematic views of a semiconductor structure according to one or more embodiments;

FIG. 4E illustrates schematic views of a semiconductor structure according to one or more embodiments; and

FIG. 4F illustrates schematic views of a semiconductor structure according to one or more embodiments.

To facilitate understanding, identical reference numerals have been used, when possible, to designate elements that are common to the figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As gate structures scale to smaller dimensions, new material structures are being sought to provide improvements. The use of high-K dielectric materials increases the dielectric constant of the gate structure over conventional gate structures that utilize materials such as silicon oxide. However, similar to silicon oxide, as the thickness of a gate structure is reduced, leakage currents increase. For example, gate leakage increases as the effective oxide thickness decreases. Hence, the inverse relationship between gate leakage and effective oxide thickness may form a limit on the performance of the transistor and the device produced.

High-K dielectric materials may provide greater channel mobility over silicon oxide at similar thicknesses. As the industry continues to seek lower effective oxide thicknesses without increased gate leakage, efforts to maximize a dielectric constant (also referred to as “K-value”) of known high-K materials are reaching limits due to morphological characteristics. Conventional technologies have struggled to overcome natural characteristics of high-K materials, which may set an upper limit in the K-value, and subsequent device remodeling in attempts to incorporate new films.

The embodiments described herein provide systems and methods for improving the characteristics of high-K dielectric materials. By producing high-K dielectric materials exhibiting a specific morphology or a grain structure, higher dielectric constants and subsequent improved device performance may be enabled. In order to control grain formation in exemplary devices, treatments may be performed to provide activated substrate surfaces that can induce a specific grain growth, as well as to stabilize films after formation, which may result in a higher dielectric constant.

The embodiments described herein advantageously provide hydration chemistry that first breaks silicon-oxygen bonds or etches silicon oxide (SiOₓ) films and then functionalizes the surface with hydroxide (—OH) molecules. This differs from the standard functionalization process and produces better nucleation of the high-K dielectric layer, e.g., hafnium oxide (HfOₓ), on thermally grown silicon oxide (SiOₓ).

As used in this specification and the appended claims, the term “substrate” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

As used in this specification and the appended claims, the terms “precursor”, “reactant”, “reactive gas” and the like are used interchangeably to refer to any gaseous species that can react with the substrate surface.

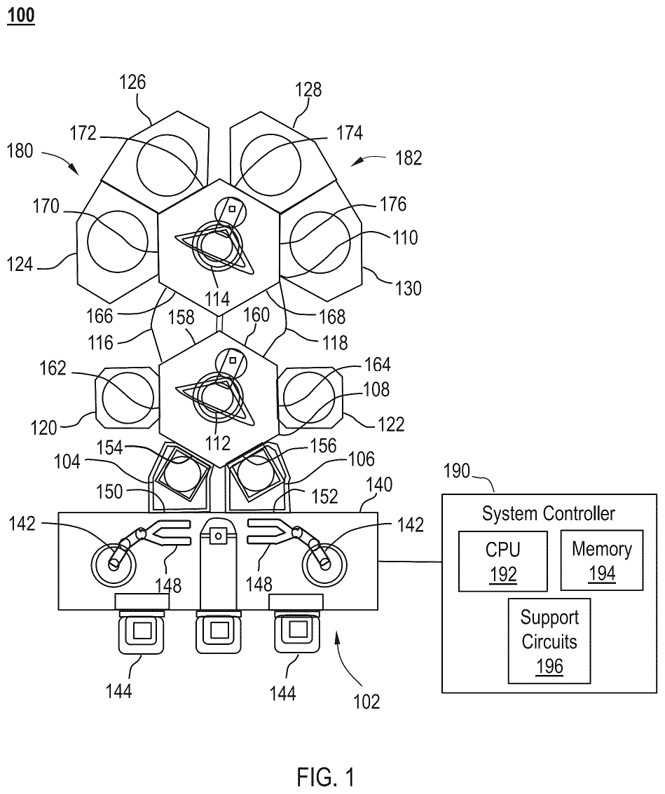

FIG. 1 is a schematic top-view diagram of an example of a multi-chamber processing system 100 according to some examples of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, wafers in the processing system 100 can be processed in and transferred between the various chambers without exposing the wafers to an ambient environment exterior to the processing system 100 (e.g., an atmospheric ambient environment such as may be present in a fab). In other embodiments, it is desired that the wafers be exposed to the ambient environment between processing steps, as will be detailed below.

In one or more embodiments, the wafers can be processed in and transferred between the various chambers in a low pressure (e.g., less than or equal to about 300 Torr) or vacuum environment without breaking the low pressure or vacuum environment between various processes performed on the wafers in the processing system 100. Accordingly, the processing system 100 may provide for an integrated solution for some processing of wafers. Any suitable processing system known to the skilled artisan may be used.

In the illustrated example of FIG. 1, the factory interface 102 includes a docking station 140 and factory interface robots 142 to facilitate transfer of wafers. The docking station 140 is configured to accept one or more front opening unified pods (FOUPs) 144. In some examples, each factory interface robot 142 generally comprises a blade 148 disposed on one end of the respective factory interface robot 142 configured to transfer the wafers from the factory interface 102 to the load lock chambers 104, 106.

The load lock chambers 104, 106 have respective ports 150, 152 coupled to the factory interface 102 and respective ports 154, 156 coupled to the transfer chamber 108. The transfer chamber 108 further has respective ports 158, 160 coupled to the holding chambers 116, 118 and respective ports 162, 164 coupled to processing chambers 120, 122. Similarly, the transfer chamber 110 has respective ports 166, 168 coupled to the holding chambers 116, 118 and respective ports 170, 172, 174, 176 coupled to processing chambers 124, 126, 128, 130. The ports 154, 156, 158, 160, 162, 164, 166, 168, 170, 172, 174, 176 can be, for example, slit valve openings with slit valves for passing wafers therethrough by the transfer robots 112, 114 and for providing a seal between respective chambers to prevent a gas from passing between the respective chambers. Generally, any port is open for transferring a wafer therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 142 transfers a wafer from a FOUP 144 through a port 150 or 152 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the wafer between, for example, the atmospheric environment of the factory interface 102 and the low pressure or vacuum environment of the transfer chamber 108.

With the wafer in the load lock chamber 104 or 106 that has been pumped down, the transfer robot 112 transfers the wafer from the load lock chamber 104 or 106 into the transfer chamber 108 through the port 154 or 156. The transfer robot 112 is then capable of transferring the wafer to and/or between any of the processing chambers 120, 122 through the respective ports 162, 164 for processing and the holding chambers 116, 118 through the respective ports 158, 160 for holding to await further transfer. Similarly, the transfer robot 114 is capable of accessing the wafer in the holding chamber 116 or 118 through the port 166 or 168 and is capable of transferring the wafer to and/or between any of the processing chambers 124, 126, 128, 130 through the respective ports 170, 172, 174, 176 for processing and the holding chambers 116, 118 through the respective ports 166, 168 for holding to await further transfer. The transfer and holding of the wafer within and among the various chambers can be in the low pressure or vacuum environment provided by the gas and pressure control system.

The processing chambers 120, 122, 124, 126, 128, 130 can be any appropriate chamber for processing a wafer. In some embodiments, the processing chamber 120 can be capable of performing an annealing process, the processing chamber 122 can be capable of performing a cleaning process, and the processing chambers 124, 126, 128, 130 can be capable of performing epitaxial growth processes. In some examples, the processing chamber 122 can be capable of performing a cleaning process, the processing chamber 120 can be capable of performing an etch process, and the processing chambers 124, 126, 128, 130 can be capable of performing respective epitaxial growth processes. The processing chamber 122 may be any suitable preclean chamber known to the skilled artisan. The processing chamber 120 may be any suitable etch chamber known to the skilled artisan.

A system controller 190 is coupled to the processing system 100 for controlling the processing system 100 or components thereof. For example, the system controller 190 may control the operation of the processing system 100 using a direct control of the chambers 104, 106, 108, 116, 118, 110, 120, 122, 124, 126, 128, 130 of the processing system 100 or by controlling controllers associated with the chambers 104, 106, 108, 116, 118, 110, 120, 122, 124, 126, 128, 130. In operation, the system controller 190 enables data collection and feedback from the respective chambers to coordinate performance of the processing system 100.

The system controller 190 generally includes a central processing unit (CPU) 192, memory 194, and support circuits 196. The CPU 192 may be one of any form of a general-purpose processor that can be used in an industrial setting. The memory 194, or non-transitory computer-readable medium, is accessible by the CPU 192 and may be one or more of memory such as random-access memory (RAM), read only memory (ROM), floppy disk, hard disk, or any other form of digital storage, local or remote. The support circuits 196 are coupled to the CPU 192 and may comprise cache, clock circuits, input/output subsystems, power supplies, and the like. The various methods disclosed herein may generally be implemented under the control of the CPU 192 by the CPU 192 executing computer instruction code stored in the memory 194 (or in memory of a particular process chamber) as, for example, a software routine. When the computer instruction code is executed by the CPU 192, the CPU 192 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

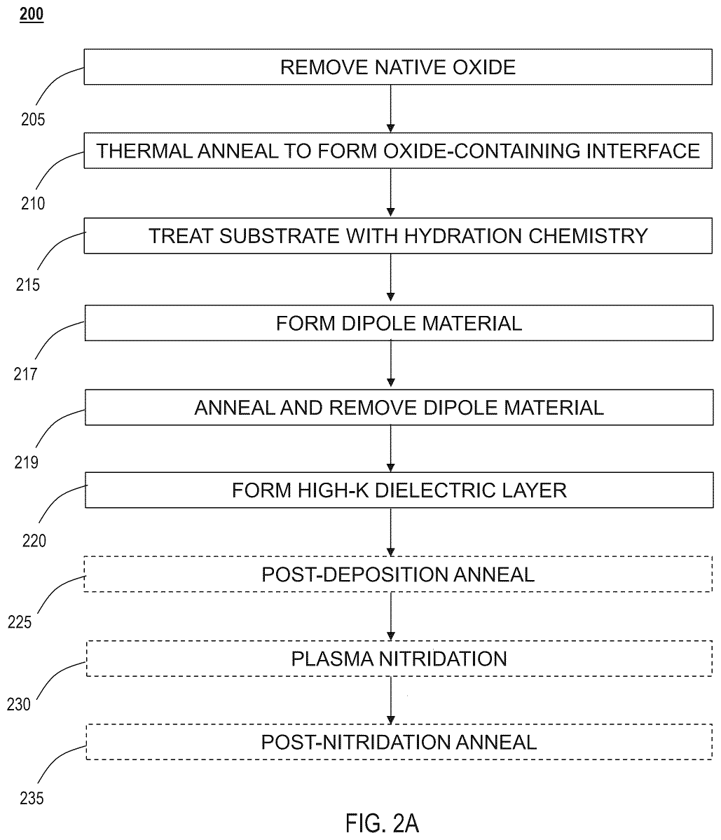

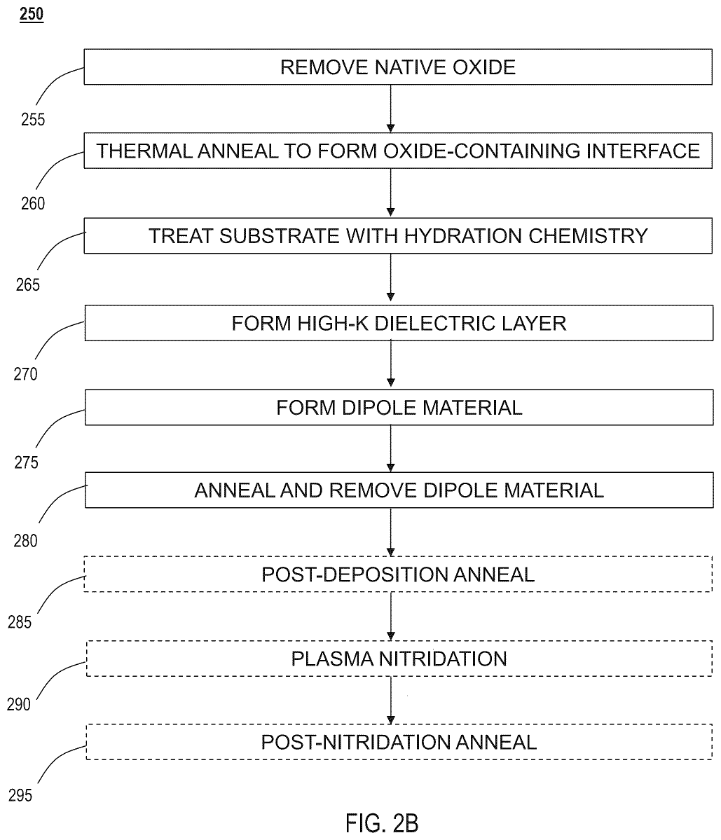

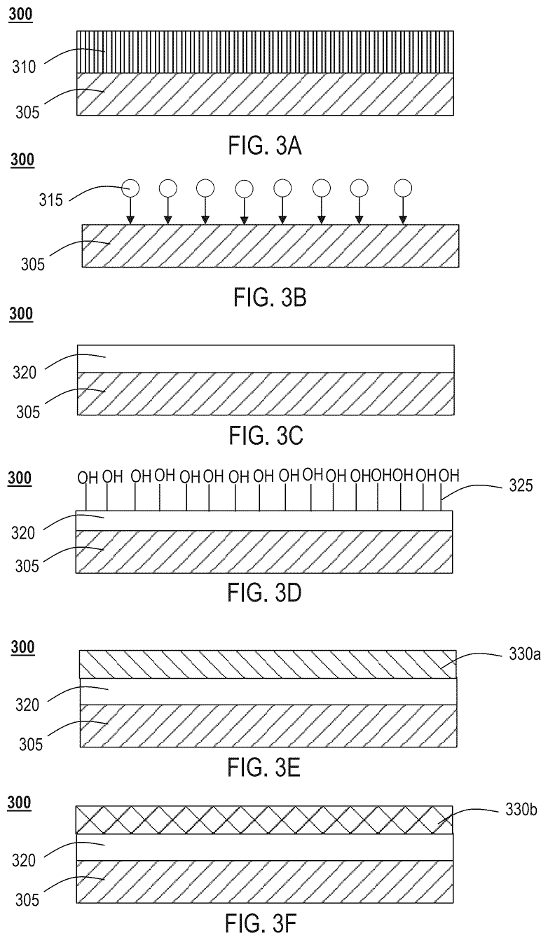

FIG. 2A is a process flow diagram of a method 200 of forming a semiconductor structure 300 according to one or more implementations of the present disclosure. FIGS. 3A to 3F are cross-sectional views of a portion of the semiconductor structure 300 corresponding to various states of the method 200. It should be understood that FIGS. 3A to 3F illustrate only partial schematic views of the semiconductor structure 300, and the semiconductor structure 300 may contain any number of transistor sections and additional materials having aspects as illustrated in the figures. It should also be noted although the method steps illustrated in FIG. 2A are described sequentially, other process sequences that include one or more method steps that have been omitted and/or added, and/or has been rearranged in another desirable order, fall within the scope of the embodiments of the disclosure provided herein.

Method 200 may include one or more operations prior to the initiation of the stated method operations, including front end processing, deposition, etching, polishing, cleaning, or any other operations that may be performed prior to the described operations. The method may include a number of optional operations as denoted in the figure, which may or may not specifically be associated with the method according to the present technology. For example, many of the operations are described in order to provide a broader scope of the structural formation process, but are not critical to the technology, or may be performed by alternative methodology as will be discussed further below.

As illustrated in FIG. 3A, the semiconductor structure may represent a device 300 after certain processing has been completed. For example, substrate 305 may be a planar material, or may be a structured device, which may include one or more materials configured as or defining posts, trenches, or other structures as would be understood are similarly encompassed by the present technology. Substrate 305 may include any number of materials including silicon or silicon-containing materials such as oxides, nitrides, and carbides of silicon, as well as any other materials that may be incorporated within a structure.

One or more material layers may be formed over some or all of substrate 305, as well as formed at least partially within the substrate, to produce a structure that may be a planarized or structured material in embodiments. As non-limiting examples, substrate 305 may be or include silicon, or may include a surface amount of silicon formed over an additional material, such as silicon oxide, and which may be a reduced portion of the silicon oxide leaving a silicon exposed surface. Substrate 305 may include a native oxide 310 as illustrated in FIG. 3A. The exposed material at a surface of substrate 305 may be etched, planarized, or otherwise processed to produce an intermittent pattern in some embodiments. Although illustrated as a single instance, it is to be understood that device 300 may include a small section of a larger process integration that may include any number of additional sections that may be similar or different to the objects shown. Substrate 305 may be housed or positioned in a processing region of a semiconductor processing chamber, and method 200 may be performed to produce a semiconductor material on the substrate, such as a high-k dielectric material.

In one or more embodiments, the method 200 may include pre-cleaning the substrate 305. In one or more embodiments, pre-cleaning the substrate 305 may comprise removing a native oxide 310 (as in FIG. 3A) from the substrate 305 in operation 205. The removing of native oxide 310 may be or include flowing a fluorine-containing precursor and a hydrogen-containing precursor. Fluorine-containing precursors may be or include nitrogen trifluoride as well as any other fluorine-containing precursor. Hydrogen-containing precursors may be characterized by an amine group (—NH₂), or other nitrogen-containing or hydrogen-containing group. For example, hydrogen-containing precursors may be or include nitrogen-and-hydrogen-containing precursors, such as ammonia as one non-limiting example. The flowing may include flowing the fluorine-containing precursor and the hydrogen-containing precursor into a remote plasma region. The remote plasm region may be fluidly coupled to the substrate processing region. A plasma may be formed to produce plasma effluents. A flow-rate of the fluorine-containing precursor and a flow rate of the hydrogen-containing precursor may be characterized by a hydrogen-to-fluorine atomic flow ratio of less than 1:2. The native oxide 310 may be removed by flowing the plasma effluents into the substrate processing region while forming solid by-products on the surface of the substrate. Without being bound to any particular theory, the flow may leave of a layer of fluorine on the substrate surface that promotes interface formation at operation 210 with the fluorine termination serving to enhance reliability. The solid by-products are sublimated by increasing the temperature of the substrate above a sublimation temperature of the solid by-products. After sublimation, the substrate 305 is free or substantially free of native oxide. The removing may be include removing the native oxide to a depth of up to or about 20 Å.

In one or more embodiments, the method 200 may include an etch in operation 205, which may be a remote plasma assisted dry etch process involving the simultaneous exposure of a substrate, such as substrate 305 of FIG. 3A, to H₂, NF₃, and/or NH₃ plasma by-products. Removing a native oxide in operation 205 may be an in situ dry chemical process where the substrate surface may not be exposed to atmosphere or an oxygen-containing environment. Removing a native oxide in operation 205 may be performed in a first processing chamber in some embodiments of method 200. Method 200 may include transferring the substrate from the first processing chamber to a second processing chamber prior to forming a high-k dielectric material as in operation 220. Prior to depositing the high-k dielectric layer, method 200 may include, at optional operation 217, depositing a dipole material on the treated interfacial layer, followed by, at optional operation 219, annealing the dipole material and removing the dipole material. Method 200 may include performing operations in one or more processing chambers without exposing the substrate surface to atmosphere or air. Method 200 may include maintaining a vacuum within system 100 during removal in operation 205. Maintaining an integrated vacuum may advantageously reduce surface contamination. The transferring may occur between one or more chambers on a single platform or may occur between chambers on multiple platforms. However, by utilizing a single platform, the avoidance of substrate exposure to an oxygen environment may be better secured.

In one or more embodiments, method 200 may include delivering an oxidizing atmosphere and thermally annealing the substrate surface to form an oxide-containing interface in operation 210. In one or more embodiments, the oxidizing atmosphere 315 comprises one or more of nitrous oxide, oxygen, or radical oxygen containing chemistries. The oxidizing atmosphere 315, e.g., nitrous oxide, delivered to the substrate 305 as in FIG. 3B may help to control how much of the substrate 305, having a surface free of native oxide, may be oxidized to form the oxide-containing interface 320 as in FIG. 3C. Operation 210 may include a thermal based reaction using steam, such as an in situ steam generation process whereby oxidation takes place at a lower rate as compared with conventional thermal techniques utilizing hydrogen and/or oxygen. The oxidizing atmosphere 315, e.g., specifically, the nitrogen of the nitrous oxide, may serve as a carrier for oxygen and may not become part of the interface or substrate. The oxide-containing interface formed may be high quality and highly ordered, meaning a crystallographic structure free of or substantially free of defects. This may provide an interface 320 that may prevent nitrogen in subsequent operations, such as the pre-treatment/functionalization in operation 215, from accessing closely to the channel region, thus preventing leakage. The resultant oxide-containing interface 320 may include silicon dioxide. The oxide-containing interface 320 formed may have a thickness in a range of from 2 Å to 30 Å. In one or more embodiments, method 200 may include removal of a thicker native oxide in operation 205 that may be replaced in subsequent operations by a thinner oxide-containing interface 320.

In one or more embodiments, the method 200 may include exposing the substrate 300 to an ambient atmosphere or oxygen-containing atmosphere for a first time period of less in a range of from greater than 0 hours to less than 36 hours, including in a range of from 1 hour to 36 hours, and a range of from 3 hours to less than 36 hours, a range of from 5 hours to less than 36 hours, or a range of from 6 hours to less than 36 hours. In one or more embodiments, the substrate 300 is then treated with hydration chemistry in operation 215 to break silicon-oxygen bonds and then functionalize the interfacial layer 320 with hydroxide (—OH molecules) 325. In one or more embodiments, the substrate is treated with 130:1 to 1000:1 dilute hydrofluoric acid (DHF) to partially remove, e.g., decrease the thickness, the interfacial layer 320. In one or more embodiments, the interfacial layer has a starting thickness in a range of from 2 Å to 30 Å, and treating the interfacial layer with DHF decreases the thickness of the interfacial layer by an amount in a range of from greater than 0 Å to 5 Å, or about 1 Å, or about 2 Å, or about 3 Å or about 4 Å.

In one or more embodiments, the partially removed interfacial layer is treated with a wet chemistry. Any suitable wet chemistry process known to the skilled artisan may be used. In one or more embodiments, the partially removed interfacial layer is treated with a wet process using a solution including NH₄OH (ammonium hydroxide), H₂O₂ (hydrogen peroxide), and H₂O (water) to functionalize the remaining interfacial layer 320 surface with hydroxide (—OH) molecules 325, as illustrated in FIG. 3D. Unlike conventional processes, in one or more embodiments, operation 215 results in successful nucleation of a subsequently deposited high-K dielectric film. Without intending to be bound by theory, it is thought that the hydration chemistry treatment of operation 215 advantageously results in decreased leakage in the gate dielectric stack. After the wet process, the substrate 300 may be exposed to an ambient atmosphere or an oxygen-containing atmosphere for a time period in a range of from >0 seconds to less than 2 hours.

For example, in some embodiments the substrate may be or include an exposed surface of silicon. The substrate 305 may itself be silicon or may be some other silicon-containing material that is reduced or modified to exhibit a silicon surface. As one non-limiting example, where substrate 305 may include silicon oxide, an initial treatment with 130:1 to 1000:1 dilute hydrofluoric acid (DHF) partially removes or decreases the thickness of the interfacial layer 320. Then treatment with a wet process using a hot solution including NH₄OH (ammonium hydroxide), H₂O₂ (hydrogen peroxide), and H₂O (water) functionalizes the remaining interfacial layer 320 surface with hydroxide (—OH) molecules 325. In one or more embodiments, the wet process is performed at a temperature in a range of from about 35° C. to about 90° C.

The surface terminations in some embodiments may be or include a hydroxyl group-terminated surface. In one or more embodiments, the method 200 may then include forming a high-k dielectric material overlying the substrate at operation 220. The present technology may encompass any formation or deposition of the high-k material, although in some embodiments formation operation 220 may be or include an atomic layer deposition, or any other atomic layer deposition chamber. The formation may be performed directly after pre-treating the substrate surface and may be performed in the same chamber as the pre-treatment or in an additional chamber, such as an additional chamber incorporated on the same system, such as system 100. In some embodiments, vacuum conditions may be maintained while the substrate is transferred from the pre-treatment chamber to the deposition or formation chamber, which may limit exposure of the substrate to air.

Where an atomic layer deposition process is performed to form the high-k dielectric material, a metal-containing precursor may be delivered to the substrate to react with the pretreated surface. For example, a transition-metal-containing precursor, a poor-metal-containing precursor, or a lanthanide-metal-containing precursor may be delivered to the processing chamber to interact with the reactive ligands exposed on the substrate from the pre-treatment. An oxygen-containing precursor may then be delivered in a second operation, such as subsequent a purge of the metal-containing precursor. The metal containing precursor may be any suitable metal-containing precursor known to the skilled artisan. In one or more embodiments, the metal-containing precursor comprises a metal halide. In some embodiments, high-K dielectric layer comprises a metal selected from one or more of hafnium, zirconium, silicon, lanthanum, aluminum, titanium and strontium. This may produce an oxide layer by atomic layer deposition, such as layer 330a as illustrated in FIG. 3E. In one non-limiting example, a hafnium-containing precursor may be delivered in a first operation and an oxidant may be delivered in a second operation for producing a hafnium oxide (HfOₓ) film. Additional metal-containing precursors may include zirconium-containing precursors for producing zirconium-containing materials, as well as any other number of metal-containing precursors for producing additional metal oxide structures. For hafnium-containing precursors, and similarly for any alternative metals, the precursors may be or include halogen-containing precursors, oxygen-containing precursors, hydrogen-containing precursors, or carbon-containing precursors in any of which hafnium is incorporated.

For the oxidant, any oxygen-containing precursor may be used that may react with the metal-containing materials. For example, the oxygen-containing precursor may be or include water, diatomic oxygen, ozone, a hydroxyl-containing precursor or alcohol, nitrogen- and oxygen-containing precursors, plasma-enhanced oxygen including locally or remotely enhanced oxygen, or any other material including oxygen that may be incorporated with the metal, such as hafnium, to produce a metal oxide material layer overlying the substrate. Again, any of the metal-containing materials noted above may be used in embodiments of the present technology, and may include any of the grouped metals, which may include, and may not be limited to, hafnium, zirconium, silicon, lanthanum, aluminum, titanium, strontium, or combinations of these materials, such as, for example, hafnium silicate.

In one or more embodiments, the high-k dielectric material layer formed has a thickness in a range of from 3 Å to 50 Å.

When hydration treatments according to embodiments of the present technology are performed on a thermally or plasma or radical based silicon oxide (SiOₓ), the structure of the metal-containing material can be formed or deposited to form a gate state having less leakage compared to known hydration methods.

In one or more embodiments, the formation, including atomic layer formation may be performed at any temperature, although in some embodiments atomic layer deposition may be performed at a temperature above the temperature at which the hydration treatment is performed, regardless of whether the operations are performed in the same or different chambers. For example, the atomic layer deposition may be performed at a second temperature relative to the hydration treatment temperature, and the formation temperature may be less than or about 500° C. in embodiments, and may be less than or about 450° C., less than or about 400° C., less than or about 350° C., less than or about 300° C., less than or about 250° C., or less.

After the layer of high-k material has been formed or deposited, one or more posttreatments may be performed. In some embodiments, the substrate may be transferred from the deposition chamber to another chamber or set of chambers for post-treating the materials at optional operation 225. Similar to that explained above, the transfer may occur on a single processing system having multiple chambers, and thus the transfer from or between any of these chambers may be performed while maintaining vacuum conditions. Method 200 may then include one or more additional post-treatment operations as noted by optional operation 230 and optional operation 235. The post-treatment operations may include one or more operations performed in one or more chambers, including multiple chambers on the same cluster tool. Post-treatment operations may include an oxidation, a nitridation, and/or a thermal anneal.

As noted above, the hydration treatment operation may be performed to provide sufficient terminal moieties to afford the uniform growth described previously, while limiting excess precursor from being incorporated with the substrate. For example, an incorporated nitrogen interface may reduce mobility of the produced transistor, or how quickly a carrier can move through the structure. Although the pre-treatment described above may further improve scaling of high-k films, if not controlled, the hydration treatment may actually degrade device mobility. However, in some embodiments, one post-treatment may include oxidizing the formed high-k material with an oxygen-containing precursor.

The deposition or formation of the high-k film may produce a porous film, or a film including vacancies in the structure. By performing an oxidation operation, oxygen species may permeate the film filling vacancies as illustrated by layer 330b as illustrated in FIG. 3F, as well as producing an oxide material at the interface of the high-k material, such as optional layer 320 if not formed in previous operations described above. This may improve the underlying interface from the amine terminal groups, which may increase the mobility performance of the device. To limit an excessive increase in an underlying oxide layer, the oxidation operation may be performed for a limited time period and may be performed within any of the previously noted time ranges.

Post-treatment operations may additionally include further contacting the substrate with a nitrogen-containing precursor. The nitrogen-containing precursor may include any nitrogen-containing precursor, and may include nitrogen gas, as well as any nitrogen-containing precursor noted elsewhere. The nitrogen-containing precursor may include a plasma-activated or enhanced nitrogen-containing precursor, a thermally activated nitrogen, or some other nitrogen precursor, which may allow nitrogen radicals or nitrogen atoms to be incorporated within the high-k structure, which may stabilize the film or settle the film towards an equilibrium state. Unlike an oxidation operation, the nitridation may not increase the thickness of an underlying layer, such as silicon oxide, and may also slightly increase the k-value of the produced film.

Nitrogen incorporation may be controlled to limit the incorporation in the film, in order to maintain the structural and electrical properties. In some embodiments, a post-treatment nitridation may incorporate less than or about 20 atomic % nitrogen at a surface region of the high-k film, and may incorporate less than or about 15 atomic % nitrogen, less than or about 10 atomic % nitrogen, less than or about 8 atomic % nitrogen, less than or about 6 atomic % nitrogen, less than or about 4 atomic % nitrogen, less than or about 2 atomic % nitrogen, or less. In some embodiments, an incorporation between about 3 atomic % and about 7 atomic % may maintain a higher k-value than higher nitrogen incorporation and may better stabilize the film than lower nitrogen incorporation. By surface region may be meant an exposed surface of the material, although the nitrogen incorporation may extend to any distance within the film, and may be consistent, or form a reducing gradient through the material.

A post-treatment oxidation or nitridation may be performed at any of the temperatures noted previously, although in some embodiments the post-treatment oxidation and/or nitridation may be performed at a temperature range below or about 500° C. and may be performed at a temperature range below or about 400° C., below or about 300° C., below or about 200° C., below or about 100° C., or less depending on the operation being performed.

A post-treatment anneal may be performed subsequent to any of the operations, including any of the noted post-treatment operations. The post-treatment anneal may be performed in any chamber in which a previous operation is performed, or may involve transfer to a different chamber, such as one configured to perform a rapid thermal anneal process, for example. Again, the chamber may be incorporated on the same platform as other chambers, which may allow a transfer between chambers while maintaining vacuum conditions. The post-treatment anneal may further align the film bonding and further stabilize the film. In embodiments the post-treatment anneal may be performed at a third temperature relative to the first temperature, where the third temperature may be above or about the first temperature. For example, the post-treatment anneal may be performed at a temperature above or about 400° C., and in embodiments may be performed at a temperature above or about 500° C., above or about 600° C., above or about 700° C., above or about 800° C., above or about 900° C., or higher.

By performing a pre-treatment and/or post-treatments according to embodiments of the present technology, improved high-k materials may be produced. The layer of high-k material may be produced to any thickness including up to or about several nanometers. In one or more embodiments, the high-k dielectric layer may have a thickness in a range of from about 3 Å to about 50 Å. However, due to the preferred grain structure produced by the present technology, thinner effective oxide thickness may be produced without loss to gate leakage performance. High-k materials produced according to the present technology may be characterized by k-values greater than or about 10, and may be characterized by k-values greater than or about 15, greater than or about 20, greater 20 than or about 21, greater than or about 22, greater than or about 23, greater than or about 24, greater than or about 25, or greater.

As noted above, the present technology further allows improved dielectric constants compared to conventional technologies. Additionally, because of the produced grain structure, gate leakage currents associated with the film may be less than or about one tenth of the gate leakage current of a similar thickness film of silicon oxide, and the gate leakage currents may be less than or about one hundredth of the gate leakage current of a similar thickness film of silicon oxide, less than or about one thousandth of a similar thickness film of silicon oxide, less than or about ⅕,000 of a similar thickness film of silicon oxide, less than or about 1/10,000 of a similar thickness film of silicon oxide, less than or about 1/20,000 of a similar thickness film of silicon oxide, less than or about 1/50,000 of a similar thickness film of silicon oxide, less than or about 1/100,000 of a similar thickness film of silicon oxide, or less. By producing films according to embodiments of the present technology, formed films having a beneficial morphology may be produced, which may enhance the electrical characteristics of the film compared to conventional technologies.

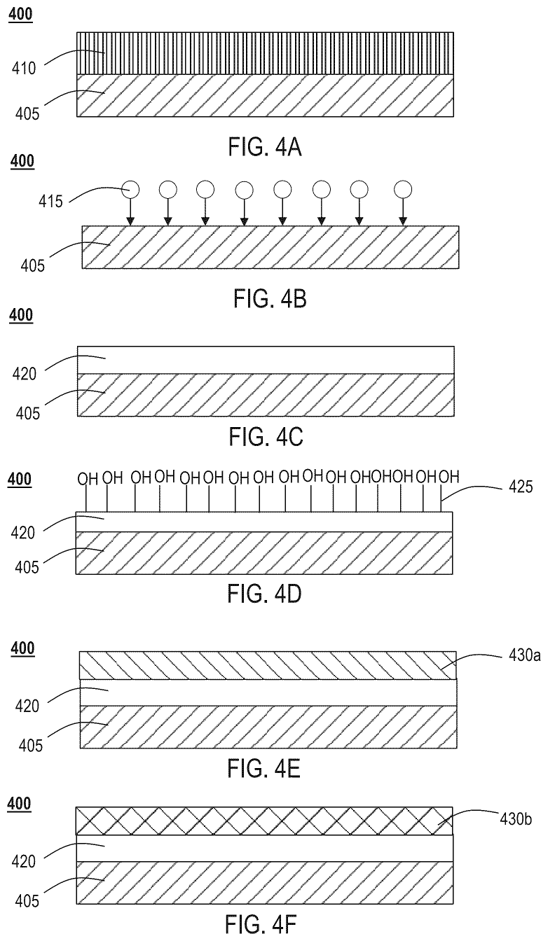

FIG. 2B is a process flow diagram of a method 250 of forming a semiconductor structure 400 according to one or more implementations of the present disclosure. FIGS. 4A to 4F are cross-sectional views of a portion of the semiconductor structure 400 corresponding to various states of the 250. It should be understood that FIGS. 4A to 4F illustrate only partial schematic views of the semiconductor structure 400, and the semiconductor structure 400 may contain any number of transistor sections and additional materials having aspects as illustrated in the figures. It should also be noted that although the method steps illustrated in FIG. 2B are described sequentially, other process sequences that include one or more method steps that have been omitted and/or added, and/or have been rearranged in another desirable order, fall within the scope of the embodiments of the disclosure provided herein.

Method 250 may include one or more operations prior to the initiation of the stated method operations, including front end processing, deposition, etching, polishing, cleaning, or any other operations that may be performed prior to the described operations. The method may include a number of optional operations as denoted in the figure, which may or may not specifically be associated with the method according to the present technology. For example, many of the operations are described in order to provide a broader scope of the structural formation process, but are not critical to the technology, or may be performed by alternative methodology as will be discussed further below.

As illustrated in FIG. 4A, the semiconductor structure may represent a device 400 after certain processing has been completed. For example, substrate 405 may be a planar material, or may be a structured device, which may include one or more materials configured as or defining posts, trenches, or other structures as would be understood are similarly encompassed by the present technology. Substrate 405 may include any number of materials including silicon or silicon-containing materials such as oxides, nitrides, and carbides of silicon, as well as any other materials that may be incorporated within a structure.

One or more material layers may be formed over some or all of substrate 405, as well as formed at least partially within the substrate, to produce a structure that may be a planarized or structured material in embodiments. As non-limiting examples, substrate 405 may be or include silicon, or may include a surface amount of silicon formed over an additional material, such as silicon oxide, and which may be a reduced portion of the silicon oxide leaving a silicon exposed surface. Substrate 405 may include a native oxide 410 as illustrated in FIG. 4A. The exposed material at the surface of substrate 405 may be etched, planarized, or otherwise processed to produce an intermittent pattern in some embodiments. Although illustrated as a single instance, it is to be understood that device 400 may include a small section of a larger process integration that may include any number of additional sections that may be similar or different to the objects shown. Substrate 405 may be housed or positioned in a processing region of a semiconductor processing chamber, and method 250 may be performed to produce a semiconductor material on the substrate, such as a high-k dielectric material.

In one or more embodiments, the method 250 may include pre-cleaning the substrate 405. In one or more embodiments, pre-cleaning the substrate 405 may comprise removing a native oxide 410 (as in FIG. 4A) from the substrate 405 in operation 255. The removing of native oxide 410 may be or include flowing a fluorine-containing precursor and a hydrogen-containing precursor. Fluorine-containing precursors may be or include nitrogen trifluoride as well as any other fluorine-containing precursor. Hydrogen-containing precursors may be characterized by an amine group (—NH₂), or other nitrogen-containing or hydrogen-containing group. For example, hydrogen-containing precursors may be or include nitrogen-and-hydrogen-containing precursors, such as ammonia as one non-limiting example. The flowing may include flowing the fluorine-containing precursor and the hydrogen-containing precursor into a remote plasma region. The remote plasm region may be fluidly coupled to the substrate processing region. A plasma may be formed to produce plasma effluents. A flow-rate of the fluorine-containing precursor and a flow rate of the hydrogen-containing precursor may be characterized by a hydrogen-to-fluorine atomic flow ratio of less than 1:2. The native oxide 410 may be removed by flowing the plasma effluents into the substrate processing region while forming solid by-products on the surface of the substrate. Without being bound to any particular theory, the flow may leave of a layer of fluorine on the substrate surface that promotes interface formation at operation 260 with the fluorine termination serving to enhance reliability. The solid by-products are sublimated by increasing the temperature of the substrate above a sublimation temperature of the solid by-products. After sublimation, the substrate 405 is free or substantially free of native oxide. The removing may be include removing the native oxide to a depth of up to or about 20 Å.

In one or more embodiments, the method 250 may include an etch in operation 255, which may be a remote plasma assisted dry etch process involving the simultaneous exposure of a substrate, such as substrate 405 of FIG. 4A, to H₂, NF₃, and/or NH₃ plasma by-products. Removing a native oxide in operation 255 may be an in situ dry chemical process where the substrate surface may not be exposed to atmosphere or an oxygen-containing environment. Removing a native oxide in operation 255 may be performed in a first processing chamber in some embodiments of method 250. Method 250 may include transferring the substrate from the first processing chamber to a second processing chamber prior to forming a high-k dielectric material as in operation 270. After depositing the high-k dielectric layer, method 250 may include, at operation 275, depositing a dipole material on the treated interfacial layer, followed by, at operation 280, annealing the dipole material and removing the dipole material. Method 250 may include performing operations in one or more processing chambers without exposing the substrate surface to atmosphere or air. Method 250 may include maintaining a vacuum within system 100 during removal in operation 255. Maintaining an integrated vacuum may advantageously reduce surface contamination. The transferring may occur between one or more chambers on a single platform or may occur between chambers on multiple platforms. However, by utilizing a single platform, the avoidance of substrate exposure to an oxygen environment may be better secured.

In one or more embodiments, method 250 may include delivering an oxidizing atmosphere and thermally annealing the substrate surface to form an oxide-containing interface in operation 260. In one or more embodiments, the oxidizing atmosphere 415 comprises one or more of nitrous oxide, oxygen, or radical oxygen containing chemistries. The oxidizing atmosphere 415, e.g., nitrous oxide, delivered to the substrate 405 as in FIG. 4B may help to control how much of the substrate 405, having a surface free of native oxide, may be oxidized to form the oxide-containing interface 420 as in FIG. 4C. Operation 260 may include a thermal based reaction using steam, such as an in situ steam generation process whereby oxidation takes place at a lower rate as compared with conventional thermal techniques utilizing hydrogen and/or oxygen. The oxidizing atmosphere 415, e.g., specifically, the nitrogen of the nitrous oxide, may serve as a carrier for oxygen and may not become part of the interface or substrate. The oxide-containing interface formed may be high quality and highly ordered, meaning a crystallographic structure free of or substantially free of defects. This may provide an interface 420 that may prevent nitrogen in subsequent operations, such as the pre-treatment/functionalization in operation 265, from accessing closely to the channel region, thus preventing leakage. The resultant oxide-containing interface 420 may include silicon dioxide. The oxide-containing interface 420 formed may have a thickness in a range of from 2 Å to 30 Å. In one or more embodiments, Method 250 may include removal of a thicker native oxide in operation 255 that may be replaced in subsequent operations by a thinner oxide-containing interface 420.

In one or more embodiments, the method 250 may include exposing the substrate 400 to an ambient atmosphere or oxygen-containing atmosphere for a first time period of less in a range of from greater than 0 hours to less than 36 hours, including in a range of from 1 hour to 36 hours, and a range of from 3 hours to less than 36 hours, a range of from 5 hours to less than 36 hours, or a range of from 6 hours to less than 36 hours. In one or more embodiments, the substrate 400 is then treated with hydration chemistry in operation 265 to break silicon-oxygen bonds and then functionalize the interfacial layer 420 with hydroxide (—OH molecules) 425, as illustrated in FIG. 4D. In one or more embodiments, the substrate is treated with 130:1 to 1000:1 dilute hydrofluoric acid (DHF) to partially remove, e.g., decrease the thickness, the interfacial layer 420. In one or more embodiments, the interfacial layer has a starting thickness in a range of from 2 Å to 30 Å, and treating the interfacial layer with DHF decreases the thickness of the interfacial layer by an amount in a range of from greater than 0 Å to 5 Å, or about 1 Å, or about 2 Å, or about 3 Å or about 4 Å.

In one or more embodiments, the partially removed interfacial layer is treated with a wet chemistry. Any suitable wet chemistry process known to the skilled artisan may be used. In one or more embodiments, the partially removed interfacial layer is treated with a wet process using a solution including H₂O₂ (hydrogen peroxide) and H₂O (water) to functionalize the remaining interfacial layer 420 surface with hydroxide (—OH) molecules 425, as illustrated in FIG. 4D. Unlike conventional processes, in one or more embodiments, operation 265 results in successful nucleation of a subsequently deposited high-K dielectric film. Without intending to be bound by theory, it is thought that the hydration chemistry treatment of operation 265 advantageously results in decreased leakage in the gate dielectric stack. After the wet process, the substrate 400 may be exposed to an ambient atmosphere or an oxygen-containing atmosphere for a time period in a range of from >0 seconds to less than 2 hours.

For example, in some embodiments the substrate may be or include an exposed surface of silicon. The substrate 405 may itself be silicon or may be some other silicon-containing material that is reduced or modified to exhibit a silicon surface. As one non-limiting example, where substrate 405 may include silicon oxide, an initial treatment with 130:1 to 1000:1 dilute hydrofluoric acid (DHF) partially removes or decreases the thickness of the interfacial layer 420. Then treatment with a wet process using a hot solution including H₂O₂ (hydrogen peroxide) and H₂O (water) functionalizes the remaining interfacial layer 420 surface with hydroxide (—OH) molecules 425. In one or more embodiments, the wet process is performed at a temperature in a range of from about 35° C. to about 90° C.

The surface terminations in some embodiments may be or include a hydroxyl group-terminated surface. In one or more embodiments, the method 250 may then include forming a high-k dielectric material overlying the substrate at operation 270. The present technology may encompass any formation or deposition of the high-k material, although in some embodiments formation operation 270 may be or include an atomic layer deposition, or any other atomic layer deposition chamber. The formation may be performed directly after pre-treating the substrate surface and may be performed in the same chamber as the pre-treatment or in an additional chamber, such as an additional chamber incorporated on the same system, such as system 100. In some embodiments, vacuum conditions may be maintained while the substrate is transferred from the pre-treatment chamber to the deposition or formation chamber, which may limit exposure of the substrate to air.

Where an atomic layer deposition process is performed to form the high-k dielectric material, a metal-containing precursor may be delivered to the substrate to react with the pretreated surface. For example, a transition-metal-containing precursor, a poor-metal-containing precursor, or a lanthanide-metal-containing precursor may be delivered to the processing chamber to interact with the reactive ligands exposed on the substrate from the pre-treatment. An oxygen-containing precursor may then be delivered in a second operation, such as subsequent a purge of the metal-containing precursor. The metal containing precursor may be any suitable metal-containing precursor known to the skilled artisan. In one or more embodiments, the metal-containing precursor comprises a metal halide. In some embodiments, high-K dielectric layer comprises a metal selected from one or more of hafnium, zirconium, silicon, lanthanum, aluminum, titanium and strontium. This may produce a high-k dielectric oxide layer by atomic layer deposition, such as layer 430a as illustrated in FIG. 4E. In one non-limiting example, a hafnium-containing precursor may be delivered in a first operation and an oxidant may be delivered in a second operation for producing a hafnium oxide (HfOₓ) film. Additional metal-containing precursors may include zirconium-containing precursors for producing zirconium-containing materials, as well as any other number of metal-containing precursors for producing additional metal oxide structures. For hafnium-containing precursors, and similarly for any alternative metals, the precursors may be or include halogen-containing precursors, oxygen-containing precursors, hydrogen-containing precursors, or carbon-containing precursors in any of which hafnium is incorporated.

For the oxidant, any oxygen-containing precursor may be used that may react with the metal-containing materials. For example, the oxygen-containing precursor may be or include water, diatomic oxygen, ozone, a hydroxyl-containing precursor or alcohol, nitrogen- and oxygen-containing precursors, plasma-enhanced oxygen including locally or remotely enhanced oxygen, or any other material including oxygen that may be incorporated with the metal, such as hafnium, to produce a metal oxide material layer overlying the substrate. Again, any of the metal-containing materials noted above may be used in embodiments of the present technology, and may include any of the grouped metals, which may include, and may not be limited to, hafnium, zirconium, silicon, lanthanum, aluminum, titanium, strontium, or combinations of these materials, such as, for example, hafnium silicate.

In one or more embodiments, the high-k dielectric material layer formed has a thickness in a range of from 3 Å to 50 Å.

When hydration treatments according to embodiments of the present technology are performed on a thermally or plasma or radical based silicon oxide (SiOₓ), the structure of the metal-containing material can be formed or deposited to form a gate state having less leakage compared to known hydration methods.

In one or more embodiments, the formation, including atomic layer formation may be performed at any temperature, although in some embodiments atomic layer deposition may be performed at a temperature above the temperature at which the hydration treatment is performed, regardless of whether the operations are performed in the same or different chambers. For example, the atomic layer deposition may be performed at a second temperature relative to the hydration treatment temperature, and the formation temperature may be less than or about 500° C. in embodiments, and may be less than or about 450° C., less than or about 400° C., less than or about 350° C., less than or about 300° C., less than or about 250° C., or less.

After the layer of high-k material has been formed or deposited, one or more posttreatments may be performed. In some embodiments, the substrate may be transferred from the deposition chamber to another chamber or set of chambers for post-treating the materials at optional operation 285. Similar to that explained above, the transfer may occur on a single processing system having multiple chambers, and thus the transfer from or between any of these chambers may be performed while maintaining vacuum conditions. Method 250 may then include one or more additional post-treatment operations as noted by optional operation 290 and optional operation 295. The post-treatment operations may include one or more operations performed in one or more chambers, including multiple chambers on the same cluster tool. Post-treatment operations may include an oxidation, a nitridation, and/or a thermal anneal.

As noted above, the hydration treatment operation may be performed to provide sufficient terminal moieties to afford the uniform growth described previously, while limiting excess precursor from being incorporated with the substrate. For example, an incorporated nitrogen interface may reduce mobility of the produced transistor, or how quickly a carrier can move through the structure. Although the pre-treatment described above may further improve scaling of high-k films, if not controlled, the hydration treatment may actually degrade device mobility. However, in some embodiments, one post-treatment may include oxidizing the formed high-k material with an oxygen-containing precursor.

The deposition or formation of the high-k film may produce a porous film, or a film including vacancies in the structure. By performing an oxidation operation, oxygen species may permeate the film filling vacancies as illustrated by layer 430b as illustrated in FIG. 4F, as well as producing an oxide material at the interface of the high-k material, such as optional layer 420 if not formed in previous operations described above. This may improve the underlying interface from the amine terminal groups, which may increase the mobility performance of the device. To limit an excessive increase in an underlying oxide layer, the oxidation operation may be performed for a limited time period and may be performed within any of the previously noted time ranges.

Post-treatment operations may additionally include further contacting the substrate with a nitrogen-containing precursor. The nitrogen-containing precursor may include any nitrogen-containing precursor, and may include nitrogen gas, as well as any nitrogen-containing precursor noted elsewhere. The nitrogen-containing precursor may include a plasma-activated or enhanced nitrogen-containing precursor, a thermally activated nitrogen, or some other nitrogen precursor, which may allow nitrogen radicals or nitrogen atoms to be incorporated within the high-k structure, which may stabilize the film or settle the film towards an equilibrium state. Unlike an oxidation operation, the nitridation may not increase the thickness of an underlying layer, such as silicon oxide, and may also slightly increase the k-value of the produced film.

Nitrogen incorporation may be controlled to limit the incorporation in the film, in order to maintain the structural and electrical properties. In some embodiments, a post-treatment nitridation may incorporate less than or about 20 atomic % nitrogen at a surface region of the high-k film, and may incorporate less than or about 15 atomic % nitrogen, less than or about 10 atomic % nitrogen, less than or about 8 atomic % nitrogen, less than or about 6 atomic % nitrogen, less than or about 4 atomic % nitrogen, less than or about 2 atomic % nitrogen, or less. In some embodiments, an incorporation between about 3 atomic % and about 7 atomic % may maintain a higher k-value than higher nitrogen incorporation and may better stabilize the film than lower nitrogen incorporation. By surface region may be meant an exposed surface of the material, although the nitrogen incorporation may extend to any distance within the film, and may be consistent, or form a reducing gradient through the material.

A post-treatment oxidation or nitridation may be performed at any of the temperatures noted previously, although in some embodiments the post-treatment oxidation and/or nitridation may be performed at a temperature range below or about 500° C. and may be performed at a temperature range below or about 400° C., below or about 300° C., below or about 200° C., below or about 100° C., or less depending on the operation being performed.

A post-treatment anneal may be performed subsequent to any of the operations, including any of the noted post-treatment operations. The post-treatment anneal may be performed in any chamber in which a previous operation is performed, or may involve transfer to a different chamber, such as one configured to perform a rapid thermal anneal process, for example. Again, the chamber may be incorporated on the same platform as other chambers, which may allow a transfer between chambers while maintaining vacuum conditions. The post-treatment anneal may further align the film bonding and further stabilize the film. In embodiments the post-treatment anneal may be performed at a third temperature relative to the first temperature, where the third temperature may be above or about the first temperature. For example, the post-treatment anneal may be performed at a temperature above or about 400° C., and in embodiments may be performed at a temperature above or about 500° C., above or about 600° C., above or about 700° C., above or about 800° C., above or about 900° C., or higher.

By performing a pre-treatment and/or post-treatments according to embodiments of the present technology, improved high-k materials may be produced. The layer of high-k material may be produced to any thickness including up to or about several nanometers. In one or more embodiments, the high-k dielectric layer may have a thickness in a range of from about 3 Å to about 50 Å. However, due to the preferred grain structure produced by the present technology, thinner effective oxide thickness may be produced without loss to gate leakage performance. High-k materials produced according to the present technology may be characterized by k-values greater than or about 10, and may be characterized by k-values greater than or about 15, greater than or about 20, greater 20 than or about 21, greater than or about 22, greater than or about 23, greater than or about 24, greater than or about 25, or greater.

As noted above, the present technology further allows improved dielectric constants compared to conventional technologies. Additionally, because of the produced grain structure, gate leakage currents associated with the film may be less than or about one tenth of the gate leakage current of a similar thickness film of silicon oxide, and the gate leakage currents may be less than or about one hundredth of the gate leakage current of a similar thickness film of silicon oxide, less than or about one thousandth of a similar thickness film of silicon oxide, less than or about ⅕,000 of a similar thickness film of silicon oxide, less than or about 1/10,000 of a similar thickness film of silicon oxide, less than or about 1/20,000 of a similar thickness film of silicon oxide, less than or about 1/50,000 of a similar thickness film of silicon oxide, less than or about 1/100,000 of a similar thickness film of silicon oxide, or less. By producing films according to embodiments of the present technology, formed films having a beneficial morphology may be produced, which may enhance the electrical characteristics of the film compared to conventional technologies.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of forming a semiconductor structure, the method comprising:
pre-cleaning a substrate surface to remove native oxide and form a pre-cleaned substrate surface;
exposing the pre-cleaned substrate surface to an oxidizing atmosphere and thermally annealing to form an interfacial layer on the pre-cleaned substrate surface;
exposing the interfacial layer to an ambient atmosphere, the interfacial layer exposed to the ambient atmosphere for a first time period;
treating the interfacial layer with hydration chemistry to form a treated interfacial layer, the interfacial layer treated with hydration chemistry for a second time period; and
depositing a high-K dielectric layer on the treated interfacial layer.

2. The method of claim 1, wherein the first time period is in a range of from greater than 0 hours to less than 36 hours, and the second time period is less than 2 hours.

3. The method of claim 1, wherein pre-cleaning the substrate comprises an in situ dry chemical process.

4. The method of claim 1, wherein the oxidizing atmosphere comprises one or more of nitrous oxide, oxygen, or radical oxygen containing chemistries.

5. The method of claim 1, wherein treating the interfacial layer with hydration chemistry comprises treating the interfacial layer with a 130:1 to 1000:1 dilute hydrofluoric acid (DHF) solution to partially remove the interfacial layer, and exposing the partially removed interfacial layer to a solution comprising hydrogen peroxide (H₂O₂) to form a hydroxide (—OH) terminated interfacial layer.

6. The method of claim 5, wherein the solution the partially removed interfacial layer is exposed to further comprises ammonium hydroxide (NH₄OH).

7. The method of claim 5, wherein partially removing the interfacial layer comprising decreasing a thickness of the interfacial layer by an amount in a range of from >0 Å to 5 Å.

8. The method of claim 1, wherein hydration chemistry occurs at a temperature in a range of from 35° C. to 90° C.

9. The method of claim 1, further comprising thermally annealing the high-K dielectric layer.

10. The method of claim 1, wherein the high-K dielectric layer comprises one or more of hafnium, zirconium, silicon, lanthanum, aluminum, titanium and strontium.

11. The method of claim 1, further comprising, prior to depositing the high-K dielectric layer:
depositing a dipole material on the treated interfacial layer;
annealing the dipole material;
and removing the dipole material.

12. The method of claim 1, further comprising, after depositing the high-K dielectric layer:
depositing a dipole material on the high-K dielectric layer;
annealing the dipole material;
and removing the dipole material.

13. A method of forming a semiconductor structure, the method comprising:
pre-cleaning a substrate in a first semiconductor processing chamber to remove native oxide and form a pre-cleaned substrate surface;
transferring the substrate to a second semiconductor processing chamber without breaking vacuum conditions;
exposing the pre-cleaned substrate surface to an oxidizing atmosphere and thermally annealing to form an interfacial layer on the pre-cleaned substrate surface;
transferring the substrate to a third semiconductor processing chamber while exposing the interfacial layer to an ambient atmosphere, the interfacial layer exposed to the ambient atmosphere for a first time period;
treating the interfacial layer with hydration chemistry to form a treated interfacial layer, the treating of the interfacial layer occurring for a second time period;
transferring the substrate to a fourth semiconductor processing chamber without breaking vacuum conditions; and
depositing a high-K dielectric layer on the treated interfacial layer using an atomic layer deposition process comprising a metal halide and water.

14. The method of claim 13, wherein the first time period is in a range of from greater than 0 hours to less than 36 hours, and the second time period is less than 2 hours.

15. The method of claim 13, wherein pre-cleaning the substrate comprises an in situ dry chemical process.

16. The method of claim 13, wherein the oxidizing atmosphere comprises one or more of nitrous oxide, oxygen, or radical oxygen containing chemistries.

17. The method of claim 13, wherein treating the interfacial layer with hydration chemistry comprises treating the interfacial layer with a 130:1 to 1000:1 dilute hydrofluoric acid (DHF) solution to partially remove the interfacial layer, and exposing the partially removed interfacial layer to a solution comprising hydrogen peroxide (H₂O₂) to form a hydroxide (—OH) terminated interfacial layer.

18. The method of claim 17, wherein the solution the partially removed interfacial layer is exposed to further comprises ammonium hydroxide (NH₄OH).

19. The method of claim 17, wherein partially removing the interfacial layer comprising decreasing a thickness of the interfacial layer by an amount in a range of from >0 Å to 5 Å.

20. The method of claim 13, further comprising, prior to transferring the substrate to the fourth semiconductor processing chamber without breaking vacuum conditions:
transferring the substrate to a fifth semiconductor processing chamber and depositing a dipole material on the treated interfacial layer;
annealing the dipole material;
and removing the dipole material.

21. The method of claim 13, further comprising, after depositing a high-k dielectric layer on the treated interfacial layer:
transferring the substrate to a fifth semiconductor processing chamber and depositing a dipole material on the high-x dielectric layer;
annealing the dipole material;
and removing the dipole material.

22. The method of claim 13, further comprising transferring the substrate to a sixth semiconductor processing chamber without breaking vacuum conditions and thermally annealing the high-k dielectric layer.
